(19) United States
(12) Patent Application Publication
(10) Pub. No.: US 2021/0359046 A1
(43) Pub. Date: Nov. 18, 2021

(54) ARRAY SUBSTRATE AND MANUFACTURING METHOD THEREOF

(71) Applicant: Wuhan China Star Optoelectronics Semiconductor Display Technology Co., LTD., Wuhan, Hubei (CN)

(72) Inventor: Lei WANG, Wuhan (CN)

(21) Appl. No.: 16/622,062

(22) PCT Filed: Aug. 20, 2019
(86) PCT No.: PCT/CN2019/101615

§ 371 Date: Dec. 12, 2019

(30) Foreign Application Priority Data
May 7, 2019 (CN) 201910376302.1

(51) Int. Cl. H01L 27/32; H01L 51/52; H01L 51/56

(52) U.S. Cl. CPC H01L 27/3246; H01L 51/5271; H01L 2227/323; H01L 51/5218; H01L 51/56

(57) ABSTRACT

An array substrate is provided. The array substrate includes a substrate, a first planarization layer disposed on the substrate, a second planarization layer disposed on the substrate, a partition groove formed between the first planarization layer and the second planarization layer to expose the substrate, a first electrode layer disposed on the first planarization layer, a reflective layer disposed on the second planarization layer and covering a side of the second planarization layer, and a pixel defining layer disposed on the partition groove and covering a portion of the first planarization layer and a portion of the second planarization layer. The reflective layer is configured to improve the light output and prevent light leakage from an edge of the array substrate. A manufacturing method of the array substrate is also provided.

### FIELD OF INVENTION

This disclosure relates to display technology, and more particularly, to an array substrate and a manufacturing method of the array substrate.

### BACKGROUND OF INVENTION

Organic light emitting diode (OLED) is widely used in the display technology due to its advantages of high brightness, full viewing angles, fast response times, and flexible display.

An array substrate applied to conventional organic light emitting diode comprises a planarization layer, an anode, a pixel defining layer, and a passivation layer. On the one hand, since the planarization layer is made of a transparent material, the transparent material allows the planarization layer to have high light transmittance.

When a light emitting layer emits light, not only will light be emitted upwardly by the light emitting layer, but also light will be emitted along both sides of the light emitting layer, and the planarization layer cannot effectively block lateral light emitted from both sides of the light emitting layer. Light emitted from the light emitting layer, especially lateral light, cannot be effectively blocked by the planarization layer; thus, lateral light is converted into a stray light via reflection by a metal layer in an in-plane display panel and refraction by other layers. For biometrics, such as fingerprint recognition, a signal-to-noise ratio of a product is reduced, leading to reduced recognition capability.

On the other hand, since light emitted from the light emitting layer itself emits in various directions, light is subjected to absorption and refraction loss through layers, such as a pixel defining layer. Hence, a light-emitting efficiency is less than 20%. In order to obtain higher usage brightness, power supply must be increased. Consequently, power consumption is increased, and battery life of a product is reduced.

### SUMMARY OF INVENTION

Since the planarization layer and the pixel defining layer of the array substrate of the conventional organic light emitting diode are made of the transparent materials, the lateral light of the light emitting layer cannot be effectively blocked by the planarization layer and the pixel defining layer, the light-emitting efficiency of the display panel is greatly reduced, and a signal interference is generated to the internal optical fingerprint recognition. The signal-to-noise ratio is reduced and the power consumption is increased.

The object of this disclosure is to provide an array substrate. The array substrate comprises a substrate, a first planarization layer disposed on the substrate, a second planarization layer disposed on the substrate, a partition groove formed between the first planarization layer and the second planarization layer to expose the substrate, a first electrode layer disposed on the first planarization layer, a reflective layer disposed on the second planarization layer and covering a side of the second planarization layer, and a pixel defining layer disposed on the partition groove and covering a portion of the first planarization layer and a portion of the second planarization layer. The reflective layer extends from the second planarization layer onto the array substrate and forms a gap with the first planarization layer.

According to an embodiment of the disclosure, the array substrate further comprises a thin film transistor layer disposed on the substrate, and the first planarization layer is correspondingly disposed on the thin film transistor layer.

According to an embodiment of the disclosure, the reflective layer is disposed on the second planarization layer and covers a sidewall of the partition groove and extends onto the substrate, and the second planarization layer is disposed between the reflective layer and the substrate.

According to an embodiment of the disclosure, a material of the reflective layer is the same as a material of the first electrode layer.

According to an embodiment of the disclosure, the array substrate further comprises a light emitting layer and a second electrode layer, the light emitting layer is disposed on the first electrode layer and the reflective layer, and the second electrode layer is disposed on the light-emitting layer.

According to an embodiment of the disclosure, a thickness of the second planarization layer is greater than a thickness of the first planarization layer.

The disclosure further provides an array substrate. The array substrate comprises a substrate, a first planarization layer disposed on the substrate, a second planarization layer disposed on the substrate, a partition groove formed between the first planarization layer and the second planarization layer to expose the substrate, a first electrode layer disposed on the first planarization layer, a reflective layer disposed on the second planarization layer and covering a side of the second planarization layer, and a pixel defining layer disposed on the partition groove and covering a portion of the first planarization layer and a portion of the second planarization layer.

According to an embodiment of the disclosure, the array substrate further comprises a thin film transistor layer disposed on the substrate, and the first planarization layer is correspondingly disposed on the thin film transistor layer.

According to an embodiment of the disclosure, the reflective layer is disposed on the second planarization layer and covers a sidewall of the partition groove and extends onto the substrate, and the second planarization layer is disposed between the reflective layer and the substrate.

According to an embodiment of the disclosure, a material of the reflective layer is the same as a material of the first electrode layer.

According to an embodiment of the disclosure, the array substrate further comprises a light emitting layer and a second electrode layer, the light emitting layer is disposed on the first electrode layer and the reflective layer, and the second electrode layer is disposed on the light-emitting layer.

According to an embodiment of the disclosure, a thickness of the second planarization layer is greater than a thickness of the first planarization layer.

In order to solve the above drawbacks, the disclosure further provides a manufacturing method of an array substrate. The manufacturing method comprises: providing a substrate; forming a first planarization layer on the substrate corresponding to the substrate using a first mask; forming a second planarization layer on the substrate corresponding to the substrate using a second mask, and forming a partition groove between the first planarization layer and the second planarization layer to expose the substrate; forming a first electrode layer on the first planarization layer using a third mask, and forming a reflective layer on the second planarization layer, wherein a side of the second planarization layer is covered by the reflective layer; and forming a pixel defining layer on a surface of the partition groove by a fourth mask and covering a portion of the first planarization layer and a portion of the second planarization layer to form a pair of the pixel defining layers spaced apart from each other.

According to an embodiment of the disclosure, the manufacturing method further comprises forming a thin film transistor layer disposed on the substrate, and the first planarization layer is correspondingly disposed on the thin film transistor layer.

According to an embodiment of the disclosure, the reflective layer is disposed on the second planarization layer and covers a sidewall of the partition groove and extends onto the substrate, and wherein the second planarization layer is disposed between the reflective layer and the substrate.

According to an embodiment of the disclosure, a material of the reflective layer is the same as a material of the first electrode layer.

Advantageous effects of the disclosure are as follows. The disclosure provides an array substrate and a manufacturing method of the array substrate. For the structure of the array substrate, a second planarization layer is disposed and a reflective layer is disposed at an edge of the second planarization layer. The reflective layer mainly provides a reflection effect, and reflects the lateral light of the light emitting layer to a light-emitting direction of the display panel, thereby preventing the lateral light of the light emitting layer from being absorbed and being refracted by other layers in the display panel. That causes absorption loss and refraction loss. The light-emitting efficiency is therefore reduced. The reflective layer achieves an effect of increasing the amount of light emitting. Moreover, the reflection effect of the reflective layer further achieves the effect of preventing light leakage at the edge of the light emitting layer. In addition, in the manufacturing method of the array substrate, the second planarization layer is further configured to prepare the second planarization layer in this disclosure, and a reflective layer is formed on an edge of the second planarization layer. The reflection effect provided by the reflective layer reflects the lateral light of the light emitting layer to the light-emitting direction of the display panel, and effectively avoids the leakage of the lateral light emitted from the light emitting layer. Therefore, the amount of light emitting is increased and the leakage of the lateral light emitted from the light emitting layer is prevented without replacing the material of the planarization layer and the pixel defining layer.

### DESCRIPTION OF DRAWINGS

FIG. 1 is a structural schematic diagram of an array substrate according to the present disclosure.

FIG. 2A to FIG. 2D are process diagrams of a manufacturing method of the array substrate according to the present disclosure.

FIG. 3 is a flowchart of the manufacturing method of the array substrate according to the present disclosure.

### DETAILED DESCRIPTION OF PREFERRED EMBODIMENTS

In order to more clearly describe the embodiments of the disclosure, the description is used to make a simple introduction of the drawings used in the following embodiments.

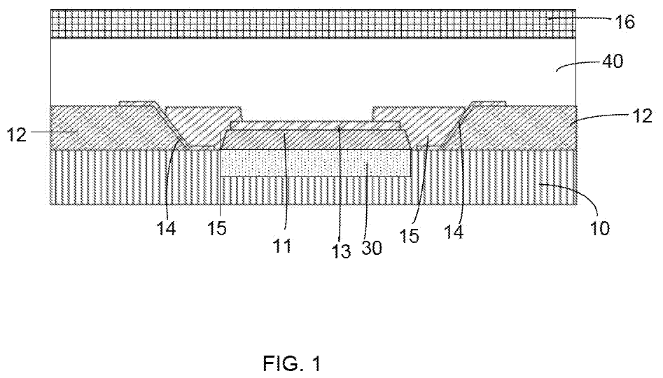

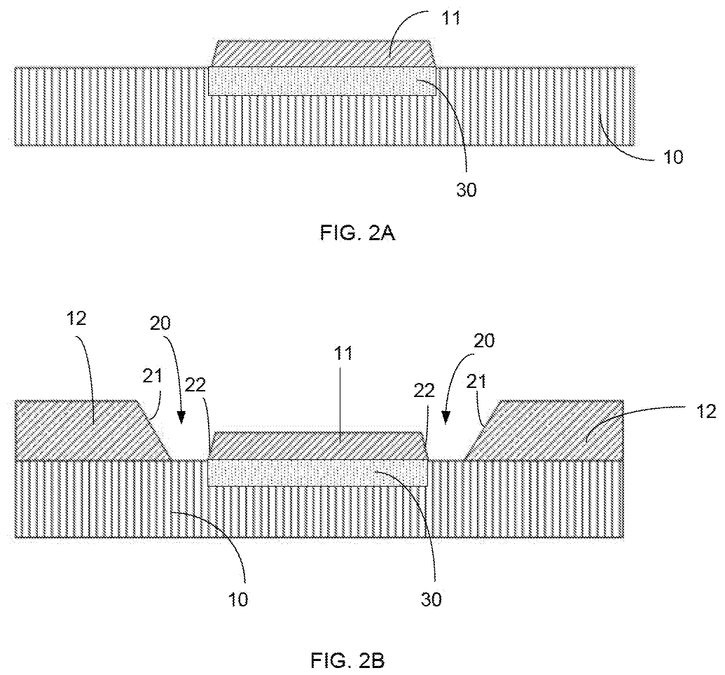

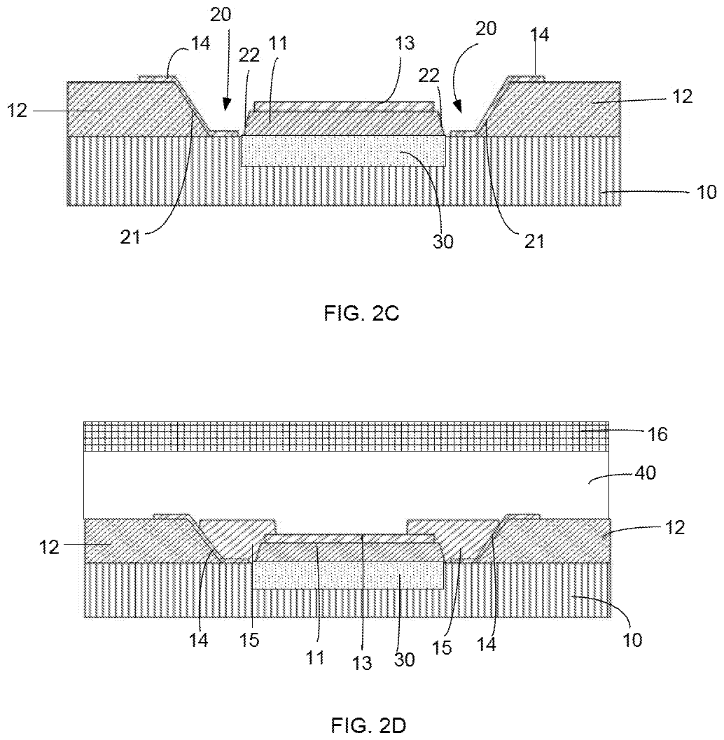

Referring to FIG. 1 and FIGS. 2A-2D, in which a structural schematic diagram of an array substrate according to the present disclosure and process diagrams of a manufacturing method of the array substrate according to the present disclosure are shown. The disclosure provides the array substrate comprising: a substrate 10, a first planarization layer 11, a second planarization layer 12, a first electrode layer 13, a reflective layer 14, and a pixel defining layer 15. The first planarization layer 11 is disposed on a portion of the substrate 10. The second planarization layer 12 is disposed on the other portion of the substrate 10, and a partition groove 20 is formed between the first planarization layer 11 and the second planarization layer 12 to expose the substrate 10. The first electrode layer 13 is disposed on the first planarization layer 11. The reflective layer 14 is disposed on the second planarization layer 12 and covers a side of the second planarization layer 12. The pixel defining layer 15 is disposed on the partition groove 20 and covers a portion of the first planarization layer 11 and a portion of the second planarization layer 12.

A thin film transistor layer 30 and an organic light emitting diode (not shown) are sequentially stacked on the substrate 10. The thin film transistor layer 30 is correspondingly disposed under the first planarization layer 11 of the substrate 10, and the substrate 10 is provided with a pixel driving circuit (not shown). The organic light emitting diode includes the first planarization layer 11, the second planarization layer 12, the first electrode layer 13, and the reflective layer 14, the pixel defining layer 15, a light emitting layer 40, and a second electrode layer 16, which are sequentially stacked in a direction away from the substrate 10. The light emitting layer 40 is disposed on the first electrode layer 13 and the reflective layer 14, and the second electrode layer 16 is disposed on the light emitting layer 40. The first electrode layer 13 is disposed above the thin film transistor layer 30 of the substrate 10, and the light emitting layer 40 and the second electrode layer 16 extend to the substrate 10 and is disposed corresponding to the other portion of the second planarization layer 12. Light emitted from the light emitting layer 40 sequentially passes through the above-mentioned layers and the substrate 10, and is emitted from a light emitting surface of the substrate 10.

The substrate 10 may be a base substrate made of a common transparent material such as glass, quartz, sapphire, or resin. In addition, the first electrode layer 13 and the second electrode layer 16 of the array substrate 10 are respectively an anode and a cathode, and the specific arrangement thereof is determined according to the design requirements of the array substrate. Alternatively, the first electrode layer 13 is a cathode, and the second electrode layer 16 is an anode correspondingly. All or part of the light emitted by the light emitting layer 40 is emitted through the substrate 10, and the lateral light of the light emitting layer 40 is reflected by the reflective layer 14 to a light emitting direction of the display panel (not shown), thereby preventing absorption and refraction loss as light passes through the above-mentioned layers the loss of the light from being absorbed and refracted by the above-mentioned layers.

In an embodiment, the partition groove 20 is disposed between the first planarization layer 11 and the second planarization layer 12 for partially covering the reflective layer 14 therein. In more detail, the array substrate includes a plurality of pixel units (not shown) arranged in an array, and each of the pixel units includes the above-mentioned organic light emitting diode and the pixel defining layer 15 disposed around the organic light emitting diode. The partition groove 20 is used to divide a connection of the pixel defining layer 15 between the pixel unit and an adjacent pixel unit. That is, at least one partition groove 20 is disposed between two adjacent pixel units. The reflective layer 14 is essentially disposed on the second planarization layer 12, and extends into the partition groove 20 to partially overlap the partition groove 20. That is, the reflective layer 14 extends to and overlaps on a sidewall 21 in the partition groove 20, and further extends to cover the array substrate 10. A gap is formed between the reflective layer 14 extending onto the array substrate 10 and the first planarization layer 11. Namely, the reflective layer 14 extending onto the array substrate 10 does not contact the first planarization layer 11. It should be noted that the reflective layer 14 covers one sidewall 21 of the partition groove 20 and does not cover the other sidewall 22 of the partition groove 20. In addition, the reflective layer 14 may be made of a light-shielding material, such as a light-shielding metal. Furthermore, the reflective layer 14 is an extension portion of the first electrode layer 13, and a material of the reflective layer 14 is the same as a material of the first electrode layer 13. In this way, the reflective layer 14 directly reflects the lateral light of the light emitting layer to the light emitting direction of the display panel. The reflection of the light on other metal layers in the display panel and the substrate 10 is reduced, and the refraction of the light on an interface between other layers and the substrate 10 is also reduced. Thus, the amount of emitted light is increased and light leakage at an edge of the light emitting layer 40 is prevented, thereby improving the display effect of a display device.

It can be seen from the above description that the array substrate provided in this embodiment reduces the occurrence of stray light formed by refraction and reflection of the lateral light inside the substrate, and at the same time, the reflective layer is further configured to reflect the emitted light to the light emitting surface, thereby improving the light emitting efficiency of the display panel.

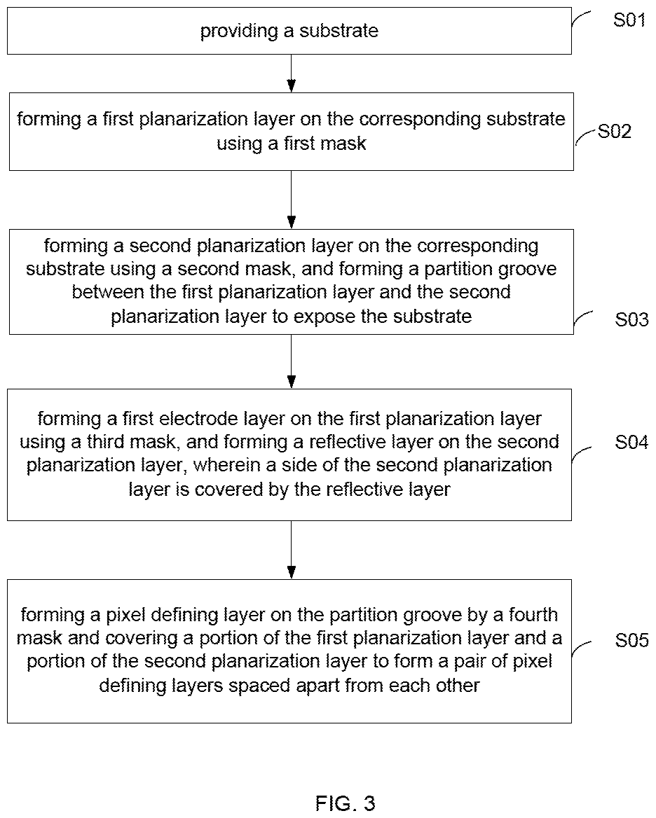

Referring to FIGS. 2A-2D and FIG. 3, in FIG. 3 a flowchart of a manufacturing method of an array substrate according to the present disclosure is shown. The disclosure provides the manufacturing method of the array substrate. The manufacturing method comprises the following steps.

In step S01, a substrate is provided.

In step S02, a first planarization layer is formed on a portion of the substrate corresponding to the substrate using a first mask. The steps S01-S02 correspond to FIG. 2A.

In step S03, a second planarization layer is formed on another portion of the substrate corresponding to the substrate using a second mask, and a partition groove is formed between the first planarization layer and the second planarization layer to expose the substrate. The step S03 corresponds to FIG. 2B.

In step S04, a first electrode layer is formed on the first planarization layer using a third mask, and a reflective layer is formed on the second planarization layer. A side of the second planarization layer is covered by the reflective layer. The step S04 corresponds to FIG. 2C.

In step S05, a pixel defining layer is formed on a surface of the partition groove by a fourth mask, and a portion of the first planarization layer and a portion of the second planarization layer are overlapped by the pixel defining layer to form a pair of pixel defining layers spaced apart from each other. The step S05 corresponds to FIG. 2D.

In step S01, the manufacturing method further includes a step of forming a thin film transistor layer on the substrate. The thin film transistor layer is correspondingly disposed under the first planarization layer 11, and the substrate is provided with a pixel driving circuit (not shown). The substrate may be a glass substrate, a sapphire substrate, a silicon-based substrate, and the like.

In step S02, a photoresist is formed on the substrate (for example, by coating), and exposure, development, and etching are performed through a first mask (for example, a halftone mask or a gray mask). Thereafter, remaining photoresist is removed to form a first planarization layer.

In step S03, an additional second mask is added, and a patterned second planarization layer is formed in advance. The patterned second planarization layer is patterned by a photolithography process, and as described in the previous step, a second planarization layer is formed after the excess portion is etched

In step S04, a patterned first electrode layer and a patterned reflective layer are formed in advance using a third mask. The patterned first electrode layer is patterned by the photolithography process, and then the first electrode layer is formed on the first planarization layer. The patterned reflective layer is patterned by the photolithography process using the third mask, and then the reflective layer is formed on the second planarization layer.

In step S05, a patterned pixel defining layer is formed using a fourth mask, and the patterned pixel defining layer is patterned by a photolithography process. The patterned pixel defining layer is formed on a surface of the partition groove and covers a portion of the first planarization layer and a portion of the second planarization layer. Thus, the pixel defining layer becomes a pair of pixel defining layers spaced apart from each other.

In step S05, the manufacturing method further includes a step of forming an organic light emitting diode (not shown) on the substrate. The organic light emitting diode comprises a first planarization layer, a second planarization layer, a first electrode layer, a reflective layer, a pixel defining layer, a light emitting layer, and a second electrode layer, which are sequentially stacked in a direction away from the substrate. The light emitting layer is disposed on the first electrode layer and the reflective layer, and the second electrode layer is disposed on the light emitting layer. The first electrode layer is disposed above a thin film transistor layer of the substrate. Light emitted from the light emitting layer passes through the above-mentioned layers and the substrate, and is emitted from a light emitting surface of the substrate.

All or part of the light emitted by the light emitting layer is emitted through the substrate, and the lateral light of the light emitting layer is reflected by the reflective layer to a light emitting direction of the display panel, thereby preventing the loss of light from being absorbed and refracted by the above-mentioned layers as passing through the above-mentioned layers.

In an embodiment, a partition groove is disposed between the first planarization layer 11 and the second planarization layer 12 to partially cover the reflective layer therein. In more detail, an array substrate includes a plurality of pixel units (not shown) arranged in an array, and each of the pixel units includes the above-mentioned organic light emitting diode and the pixel defining layer disposed around the organic light emitting diode. The partition groove is used to separate a connection of the pixel defining layer between the pixel unit and an adjacent pixel unit. That is, at least one partition groove is disposed between two adjacent pixel units. The reflective layer is essentially disposed on the second planarization layer. Moreover, the reflective layer extends into the partition groove to partially overlap the partition groove. That is, the reflective layer extends to and overlaps on a sidewall in the partition groove, and further extends to cover the array substrate. A gap is formed between the reflective layer extending onto the array substrate and the first planarization layer 11. Namely, the reflective layer extending onto the array substrate does not contact the first planarization layer. In addition, the reflective layer may be made of a light-shielding material, such as a light-shielding metal. Furthermore, the reflective layer is an extension portion of the first electrode layer, and a material of the reflective layer is the same as a material of the first electrode layer. In this way, the reflective layer directly reflects the lateral light of the light emitting layer to the light emitting direction of the display panel. The reflection of the light on an interface between other layers and the substrate is reduced, and the refraction of the light on an interface between other layers and the substrate is also reduced. Thus, the amount of emitted light is increased and light leakage at an edge of the light emitting layer is prevented, thereby improving the display effect of a display device.

It can be seen that the manufacturing method of the array substrate in this embodiment further comprises a step of forming the second planarization layer by utilizing the second mask, so that the reflective layer can be disposed on a side surface of the second planarization layer (i.e., a sidewall of the partition groove). This can reduce the occurrence of stray light caused by refraction and reflection of light inside the substrate. At the same time, the reflective layer is further configured to concentrate and reflect the emitted light to the light emitting surface, without replacing the material of the planarization layer and the pixel defining layer. The effect of increasing the amount of the emitted light and preventing light leakage at the edge of the light emitting layer is achieved.

Advantageous effects of the disclosure are as follows. The disclosure provides an array substrate and a manufacturing method of the array substrate. For the structure of the array substrate, a second planarization layer is disposed and a reflective layer is disposed at an edge of the second planarization layer. The reflective layer mainly provides a reflection effect, and reflects the lateral light of the light emitting layer to a light emitting direction of the display panel, thereby preventing the lateral light of the light emitting layer from being absorbed and refracted by other layers in the display panel, which causes absorption loss and refraction loss and subsequently reduces light emitting efficiency. Thus, the reflective layer achieves an effect of increasing the amount of light emitted. Moreover, the reflection effect of the reflective layer further achieves the effect of preventing light leakage at the edge of the light emitting layer. In addition, in the manufacturing method of the array substrate, the second mask is further configured to prepare the second planarization layer in this disclosure, and a reflective layer is formed on an edge of the second planarization layer. The reflection effect provided by the reflective layer reflects the lateral light of the light emitting layer to the light emitting direction of the display panel, and effectively prevents the leakage of the lateral light emitted from the light emitting layer. Therefore, the amount of light emitted is increased and the leakage of the lateral light emitted from the light emitting layer is prevented without replacing the material of the planarization layer and the pixel defining layer.

This disclosure has been described with preferred embodiments thereof, and it is understood that many changes and modifications to the described embodiment can be carried out without departing from the scope and the spirit of the invention.

What is claimed is:

1. An array substrate, comprising:
a substrate;
a first planarization layer disposed on the substrate;
a second planarization layer disposed on the substrate, and a partition groove formed between the first planarization layer and the second planarization layer to expose the substrate;
a first electrode layer disposed on the first planarization layer;
a reflective layer disposed on the second planarization layer and covering a side of the second planarization layer; and
a pixel defining layer disposed on the partition groove and covering a portion of the first planarization layer and a portion of the second planarization layer;
wherein the reflective layer extends from the second planarization layer onto the array substrate and forms a gap with the first planarization layer.

2. The array substrate according to claim 1, wherein the array substrate further comprises a thin film transistor layer disposed on the substrate, and the first planarization layer is correspondingly disposed on the thin film transistor layer.

3. The array substrate according to claim 1, wherein the reflective layer is disposed on the second planarization layer and covers a sidewall of the partition groove and extends onto the substrate, and wherein the second planarization layer is disposed between the reflective layer and the substrate.

4. The array substrate according to claim 1, wherein a material of the reflective layer is the same as a material of the first electrode layer.

5. The array substrate according to claim 1, wherein the array substrate further comprises a light emitting layer and a second electrode layer, the light emitting layer is disposed on the first electrode layer and the reflective layer, and the second electrode layer is disposed on the light emitting layer.

6. The array substrate according to claim 1, wherein a thickness of the second planarization layer is greater than a thickness of the first planarization layer.

7. An array substrate, comprising:
a substrate;
a first planarization layer disposed on the substrate;
a second planarization layer disposed on the substrate, and a partition groove formed between the first planarization layer and the second planarization layer to expose the substrate;
a first electrode layer disposed on the first planarization layer;
a reflective layer disposed on the second planarization layer and covering a side of the second planarization layer; and
a pixel defining layer disposed on the partition groove and covering a portion of the first planarization layer and a portion of the second planarization layer.

8. The array substrate according to claim 7, wherein the array substrate further comprises a thin film transistor layer disposed on the substrate, and the first planarization layer is correspondingly disposed on the thin film transistor layer.

9. The array substrate according to claim 7, wherein the reflective layer is disposed on the second planarization layer and covers a sidewall of the partition groove and extends onto the substrate, and wherein the second planarization layer is disposed between the reflective layer and the substrate.

10. The array substrate according to claim 7, wherein a material of the reflective layer is the same as a material of the first electrode layer.

11. The array substrate according to claim 7, wherein the array substrate further comprises a light emitting layer and a second electrode layer, the light emitting layer is disposed on the first electrode layer and the reflective layer, and the second electrode layer is disposed on the light emitting layer.

12. The array substrate according to claim 7, wherein a thickness of the second planarization layer is greater than a thickness of the first planarization layer.

13. A manufacturing method of an array substrate, comprising:
providing a substrate;
forming a first planarization layer on the corresponding substrate using a first mask;
forming a second planarization layer on the corresponding substrate using a second mask, and forming a partition groove between the first planarization layer and the second planarization layer to expose the substrate;
forming a first electrode layer on the first planarization layer using a third mask, and forming a reflective layer on the second planarization layer, wherein a side of the second planarization layer is covered by the reflective layer; and
forming a pixel defining layer on the partition groove by a fourth mask and covering a portion of the first planarization layer and a portion of the second planarization layer to form a pair of pixel defining layers spaced apart from each other.

14. The manufacturing method according to claim 13, wherein the manufacturing method further comprises forming a thin film transistor layer disposed on the substrate, and the first planarization layer is correspondingly disposed on the thin film transistor layer.

15. The manufacturing method according to claim 13, wherein the reflective layer is disposed on the second planarization layer and covers a sidewall of the partition groove and extends onto the substrate, and wherein the second planarization layer is disposed between the reflective layer and the substrate.

16. The manufacturing method according to claim 13, wherein a material of the reflective layer is the same as a material of the first electrode layer.
